(19) United States
(12) Patent Application Publication
(10) Pub. No.: US 2012/0040085 A1
(43) Pub. Date: Feb. 16, 2012

(54) METHOD FOR FORMING Cu FILM AND STORAGE MEDIUM

(75) Inventors: Yasuhiko KOJIMA, Nirasaki-shi (JP); Kenji HIWA, Nirasaki-shi (JP)

(73) Assignee: TOKYO ELECTRON LIMITED, Minato-ku (JP)

(21) Appl. No.: 13/213,725

(22) Filed: Aug. 19, 2011

Related U.S. Application Data
(63) Continuation of application No. PCT/JP10/51122, filed on Jan. 28, 2010.

(30) Foreign Application Priority Data
Feb. 19, 2009 (JP) 2009-036340

(51) Int. Cl. B05D 5/12; B05C 11/00; C23C 16/18; C23C 16/00; C23C 16/06

(52) U.S. Cl. 427/58; 427/252; 427/253; 118/697

(57) ABSTRACT

In a method for forming a Cu film, a wafer (W) is loaded into a chamber 1. Then, Cu(hfac)TMVS as a monovalent Cu β-diketone complex and a reducing agent for reducing Cu(hfac)TMVS are introduced into the chamber 1 in a vapor state. Thus, a Cu film is formed on the wafer (W) by CVD.

This application is a Continuation Application of PCT International Application No. PCT/JP2010/051122 filed on Jan. 28, 2010, which designated the United States.

### FIELD OF THE INVENTION

The present invention relates to a method for forming a Cu film by chemical vapor deposition (CVD) on a substrate such as a semiconductor substrate or the like, and a storage medium.

### BACKGROUND OF THE INVENTION

Recently, along with the trend toward high speed of semiconductor devices and miniaturization of wiring patterns, Cu having higher conductivity and electromigration resistance than Al attracts attention as a material for wiring, a Cu plating seed layer, and a contact plug.

As for a method for forming a Cu film, physical vapor deposition (PVD) such as sputtering has been widely used. However, it is disadvantageous in that a step coverage becomes poor due to miniaturization of semiconductor devices.

Therefore, as for a method for forming a Cu film, there is used CVD for forming a Cu film on a substrate by a thermal decomposition reaction of a source gas containing Cu or by a reduction reaction of the source gas by a reducing gas. A Cu film formed by CVD (CVD-Cu film) has a high step coverage and a good film formation property for a thin, long and deep pattern. Thus, the Cu film has high conformability to a fine pattern and is suitable for formation of wiring, a Cu plating seed layer and a contact plug.

In the case of using a method for forming a Cu film by CVD, there is suggested a technique for using as a film-forming material (precursor) a Cu complex such as copper hexafluoroacetylacetonate trimethylvinylsilane (Cu(hfac)TMVS) or the like and thermally decomposing the Cu complex (see, e.g., Japanese Patent Application Publication No. 2000-282242).

Meanwhile, there is suggested a technique which uses, as a barrier metal or an adhesion layer of Cu, an Ru film (CVD-Ru film) formed by CVD (see Japanese Patent Application Publication No. H10-229084). The CVD-Ru film has a high step coverage and high adhesivity to a Cu film. Hence, it is suitable for the barrier metal or the adhesion layer of Cu.

However, when a Cu film is formed by CVD, heat needs to be supplied during the film formation. Therefore, migration of Cu on the surface of the Cu film is facilitated and an agglutination reaction occurs, which makes it difficult to obtain a smooth Cu film. Although Cu(hfac)TMVS as a conventionally used film-forming source material has a good thermal decomposition characteristics at a low temperature and a good film formation property at a relatively low temperature, it is not sufficient. In the case of using Cu(hfac)TMVS, Cu is produced by a thermal decomposition reaction accompanying a disproportionate reaction, so that it is theoretically difficult to further decrease a temperature.

Further, when a monovalent β-diketone complex such as the aforementioned Cu(hfac)TMVS is used as a film-forming source material, a by-product such as Cu(hfac)₂ having a low vapor pressure is produced during the film formation and adsorbed on the surface of the formed film. Hence, the adsorption of the Cu source material is hindered, and the initial nucleus density of Cu is decreased. Accordingly, the smoothness of the Cu film is decreased.

Thus, the CVD-Cu film is not suitable for the case of requiring high smoothness or the case of requiring an extremely thin Cu film.

### SUMMARY OF THE INVENTION

In view of the above, the present invention provides a method for forming a Cu film which is capable of forming a smooth high-quality Cu film.

The present invention also provides a storage medium for storing a program for performing this film forming method.

The present inventors have performed examinations in order to obtain a Cu film having high smoothness. As a result, they have found that when a monovalent β-diketone complex as a Cu complex is used as a film-forming source material, the film formation can be performed at a lower temperature by decreasing activation energy of a Cu production reaction by adding a predetermined reducing agent and, also, the decrease in the initial nucleus density of Cu due to the adsorption hindrance of Cu can be prevented. The present invention has been conceived by the above conclusion.

In accordance with a first aspect of the present invention, there is provided a method for forming a Cu film, including loading a substrate in a processing chamber;

introducing into the processing chamber a monovalent Cu β-diketone complex and a reducing agent for reducing the monovalent Cu β-diketone complex in a vapor state; and forming a Cu film by reducing the monovalent Cu β-diketone complex by the reducing agent and depositing Cu on the substrate by CVD.

In accordance with a second aspect of the present invention, there is provided a computer readable storage medium storing a program for controlling a film forming apparatus. The program, when executed, controls the film forming apparatus to perform a method for forming a Cu film which includes: loading a substrate in a processing chamber; introducing into the processing chamber a monovalent Cu β-diketone complex and a reducing agent for reducing the monovalent Cu β-diketone complex in a vapor state; and forming a Cu film by reducing the monovalent Cu β-diketone complex by the reducing agent and depositing Cu on the substrate by CVD.

### BRIEF DESCRIPTION OF THE DRAWINGS

FIG. 1 shows a substantial cross section of an exemplary configuration of a film forming apparatus for performing a method for forming a Cu film in accordance with an embodiment of the present invention.

FIG. 2 is a cross sectional view showing an exemplary structure of a semiconductor wafer as a substrate to which the method for forming a Cu film in accordance with the embodiment of the present invention is applied.

FIG. 3 is a timing diagram showing an example of a film forming sequence.

FIG. 4 is a timing diagram showing another example of the film forming sequence.

FIG. 5 is a timing diagram showing still another example of the film forming sequence.

FIG. 6 is a cross sectional view showing a state in which a CVD-Cu film is formed as a wiring material on the semiconductor wafer having the structure shown in FIG. 2.

FIG. 7 is a cross sectional view showing a state in which a CVD-Cu film is formed as a Cu plating seed layer on the semiconductor wafer having the structure shown in FIG. 2.

FIG. 8 is a cross sectional view showing a state in which CMP is performed on the semiconductor wafer having the structure shown in FIG. 6.

FIG. 9 is a cross sectional view showing a state in which Cu plating is performed on the semiconductor wafer having the structure shown in FIG. 7.

FIG. 10 is a cross sectional view showing a state in which CMP is performed on the semiconductor wafer having the structure shown in FIG. 9.

FIG. 11 is a cross sectional view showing another exemplary structure of the semiconductor wafer serving as the substrate to which the method for forming a Cu film in accordance with the embodiment of the present invention is applied.

### DETAILED DESCRIPTION OF THE EMBODIMENTS

Hereinafter, the embodiments of the present invention will be described with reference to the accompanying drawings which form a part hereof.

### <Configuration of Film Forming Apparatus for Performing Film Forming Method of the Present Invention>

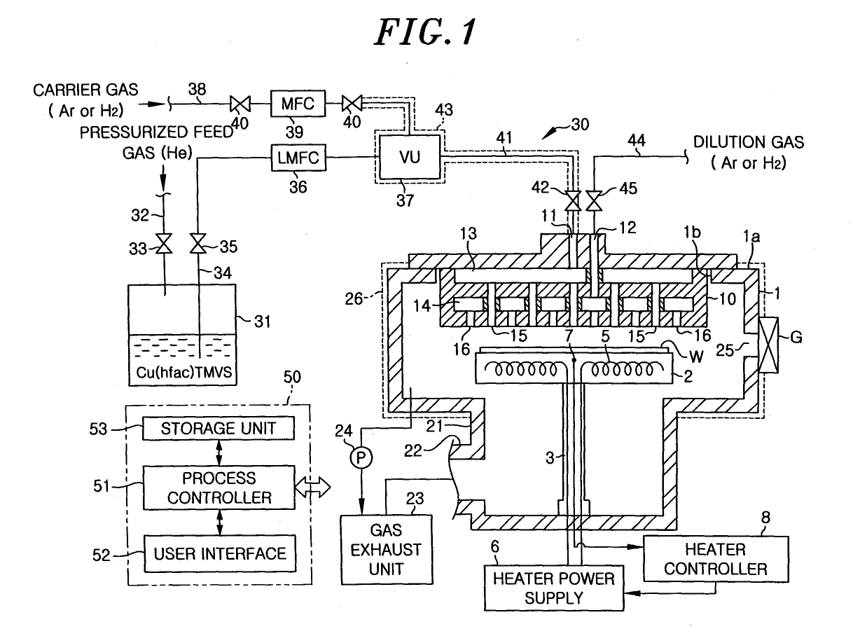

FIG. 1 is a substantial cross sectional view showing an exemplary configuration of a film forming apparatus for performing a method for forming a Cu film in accordance with an embodiment of the present invention.

A film forming apparatus 100 includes a substantially cylindrical airtight chamber 1 as a processing chamber, and a susceptor 2 provided in the chamber 1. The susceptor 2 for horizontally supporting a semiconductor wafer W as a substrate to be processed is supported by a cylindrical supporting member 3 provided at the center of the bottom portion of the chamber 1. The susceptor 2 is made of ceramic such as AlN or the like.

Further, a heater 5 is buried in the susceptor 2, and a heater power supply 6 is connected to the heater 5. Meanwhile, a thermocouple 7 is provided near the top surface of the susceptor 2, and a signal from the thermocouple 7 is transmitted to a heater controller 8. The heater controller is configured to transmit an instruction to the heater power supply 6 in accordance with the signal from the thermocouple 7 and control the wafer W to a predetermined temperature by controlling the heating of the heater 5.

A circular opening 1b is formed at a ceiling wall 1a of the chamber 1, and a shower head 10 is fitted in the circular opening 1b to protrude into the chamber 1. The shower head 10 discharges a film forming gas supplied from a gas supply mechanism 30 to be described later into the chamber 1. The shower head 10 has, at an upper portion thereof, a first inlet line 11 for introducing, as a film forming source material, a monovalent Cu ⊕-diketone complex, e.g., copper hexafluoroacetylacetonate trimethylvinylsilane (Cu(hfac)TMVS), and a second inlet line 12 for introducing a reducing agent into the chamber 1. The first second inlet lines 11 and 12 are separately provided in the shower head 10, and the film-forming gas and the reducing agent are mixed after being injected.

The inner space of the shower head 10 is separated into an upper space 13 and a lower space 14. The first inlet line 11 is connected to the upper space 13, and a first gas injection line 15 extends from the upper space 13 to the bottom surface of the shower head 10. The second inlet line 12 is connected to the lower space 14, and a second gas injection line 16 extends from the lower space 14 to the bottom surface of the shower head 10. In other words, the shower head 10 is configured to separately inject a Cu complex gas as a film-forming source material and a reducing agent through the injection lines 15 and 16, respectively.

A gas exhaust chamber 21 is provided at a bottom wall of the chamber 1 so as to protrude downward. A gas exhaust line 22 is connected to a side surface of a gas exhaust chamber 21, and a gas exhaust unit 23 including a vacuum pump, a pressure control valve or the like is connected to the gas exhaust line 22. By driving the gas exhaust unit 23, the interior of the chamber 1 can be set to a predetermined depressurized state.

Formed on the sidewall of the chamber 1 are a loading/unloading port 25 for loading and unloading the wafer W with respect to a wafer transfer chamber (not shown) and a gate valve G for opening and closing the loading/unloading port 25. Moreover, a heater 26 is provided on a wall of the chamber 1, and can control the temperature of the inner wall of the chamber 1 during the film formation.

The gas supply mechanism 30 has a film-forming source material tank 31 for storing, as a film-forming source material, a monovalent Cu β-diketone complex in a liquid state, e.g., Cu(hfac)TMVS. As for the monovalent Cu β-diketone, it is possible to use Cu(hfac)MHY, Cu(hfac)ATMS, Cu(hfac)DMDVS, Cu(hfac)TMOVS, Cu(hfac)COD or the like. In the case of using a monovalent Cu β-diketone complex in a solid state at a room temperature, it can be stored in the film-forming source material tank 31 while being dissolved in a solvent.

pressurized feed gas line 32 for supplying a pressurized feed gas such as He gas or the like is inserted from above into the film forming source material tank 31, and a valve 33 is installed in the pressurized feed gas line 32. Further, a source material discharge line 34 is inserted from above into the film forming source material tank 31, and a vaporizer (VU) 37 is connected to the other end of the source material discharge line 34. A valve 35 and a liquid mass flow controller 36 are installed in the source material discharge line 34.

By introducing a pressurized feed gas into the film-forming source material tank 31 via the pressurized feed gas line 32, a Cu complex, e.g., Cu(hfac)TMVS, in the film-forming source material tank 31 is supplied in a liquid state to the vaporizer 37. At this time, the liquid supply amount is controlled by the liquid mass flow controller 36. A carrier gas line 38 for supplying Ar or H₂ gas as a carrier gas is connected to the vaporizer 37. A mass flow controller 39 and two valves 40 positioned at both sides of the mass flow controller 39 are provided in the carrier gas line 38.

Moreover, a film forming-material gas supply line 41 for supplying a Cu complex in a vapor state toward the shower head 10 is connected to the vaporizer 37. A valve 42 is installed in the film-forming source material gas supply line 41, and the other end of the film-forming source material gas supply line 41 is connected to the first inlet line 11 of the shower head 10. Furthermore, the Cu complex vaporized by the vaporizer 37 is discharged to the film-forming source material gas supply line 41 while being carried by the carrier gas, and then is supplied into the shower head 10 from the first inlet line 11.

A heater 43 for preventing condensation of the film-forming source material gas is provided at a region including the vaporizer 37, the film-forming source material gas supply line 41, and the valve 40 disposed at the downstream side of the carrier gas supply line. The heater 43 powered by a heater power supply (not shown), and the temperature of the heater 43 is controlled by a controller (not shown).

A reducing agent supply line 44 for supplying a reducing agent in a vapor state is connected to the second inlet line 12 of the shower head 10. The reducing agent supply line 44 is connected to a reducing agent supply source 46. Besides, a valve 45 is installed near the second inlet line 12 of the reducing agent supply line 44. Moreover, a mass flow controller 47 and two valves 48 disposed at both sides of the mass flow controller 47 are installed in the reducing agent supply line 44. In addition, a reducing agent for reducing the monovalent Cu β-diketone complex is supplied from the reducing agent supply source 46 into the chamber 1 through the reducing agent supply line 44.

The film forming apparatus 100 includes a control unit 50 which is configured to control the respective components, e.g., the heater power supply 6, the gas exhaust unit 23, the mass flow controllers 36 and 39, the valves 33, 35, 40, 42 and 45 and the like, and control the temperature of the susceptor 2 by using the heater controller 8. The control unit 50 includes a process controller 51 having a micro processor (computer), a user interface 52, and a storage unit 53. The respective components of the film forming apparatus 100 are electrically connected to and controlled by the process controller 51.

The user interface 52 is connected to the process controller 51, and includes a keyboard through which an operator performs a command input to manage the respective units of the film forming apparatus 100, a display for visually displaying the operational states of the respective components of the film forming apparatus 100, and the like.

The storage unit 53 is also connected to the process controller 51, and stores therein control programs to be used in realizing various processes performed by the film forming apparatus 100 under the control of the process controller 51, control programs, i.e., processing recipes, to be used in operating the respective components of the film forming apparatus 100 to carry out a predetermined process under processing conditions, various database and the like.

The processing recipes are stored in a storage medium provided in the storage unit 53. The storage medium may be a fixed medium such as a hard disk or the like, or a portable device such as a CD-ROM, a DVD, a flash memory or the like. Alternatively, the recipes may be suitably transmitted from other devices via, e.g., a dedicated transmission line.

If necessary, a predetermined processing recipe is read out from the storage unit 53 by the instruction via the user interface 52 and is executed by the process controller 51. Accordingly, a desired process is performed in the film forming apparatus 100 under the control of the process controller 51.

<Method for Forming Cu Film in Accordance with the Embodiment of the Present Invention>

Hereinafter, a method for forming a Cu film in accordance with the present embodiment by using a film forming apparatus configured as described above will be described.

Here, a case in which Cu(hfac) TMVS as a monovalent Cu β-diketone is used as a film-forming source material will be described as an example.

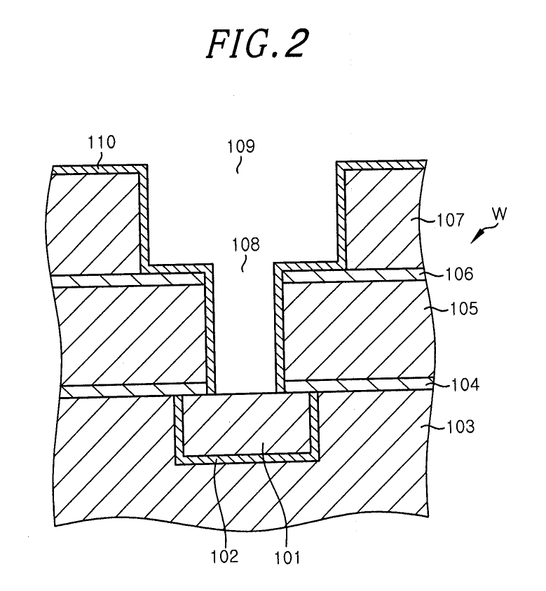

Further, a Cu film (CVD-Cu film) is formed by CVD on an Ru film (CVD-Ru film) formed by CVD. For example, as shown in FIG. 2, a CVD-Cu film is formed on a wafer W which is obtained by forming a lower Cu wiring layer 101 on a lower wiring insulating layer 103 with a CVD-Ru film 102 interposed therebetween, forming a cap insulating film 104, an interlayer insulating layer 105 and a hard mask layer 106 thereon in that order, forming an upper wiring insulating layer 107 thereon, forming a via hole 108 that penetrates through the hard mask layer 106, the interlayer insulating film 105 and the cap insulating film 104 to reach the lower Cu wiring layer 101, forming a trench 109 as a wiring groove in the upper wiring insulating layer 107, and forming a CVD-Ru film 110 as a barrier layer (diffusion prevention layer) on the inner wall of the via hole 108 and the trench 109 and the top surface of the upper wiring insulating layer 107.

Preferably, the CVD-Ru film is formed by using Ru₃(CO)₁₂ as a film-forming source material. Accordingly, a CVD-Ru film of high purity can be obtained, and a pure and robust interface of Cu and Ru can be formed. The CVD-Ru film can be formed by using an apparatus having the same configuration as that shown in FIG. 1 except that vapor generated by heating Ru₃(CO)₁₂ in a solid state at a room temperature is supplied.

In forming a Cu film, the gate valve G opens, and the wafer W having the above structure is loaded into the chamber 1 by a transfer device (not shown) and then mounted on the susceptor 2. Next, the interior of the chamber 1 is exhausted by the gas exhaust unit 23, and a pressure in the chamber 1 is set to about 1.33 to 266.6 Pa (about 10 mTorr to 2 Torr). The susceptor 2 is heated by the heater 5, and a carrier gas is supplied at a flow rate of about 100 to 1500 mL/min(sccm) via the carrier gas line 38, the vaporizer 37, the film-forming source material gas supply line 41, and the shower head 10 to obtain stable processing conditions.

When the processing conditions are stabilized, Cu(hfac)TMVS in a liquid state is vaporized at about 50 to 70° C. by the vaporizer 37 and then is introduced into the chamber 10, while the carrier gas is supplied. Further, a reducing agent in a vapor state is introduced from the reducing agent supply source 46 into the chamber 1. Thereafter, the Cu film formation onto the wafer W is started.

As for the reducing agent, one capable of reducing a monovalent Cu β-diketone complex as a film-forming source material is used. Preferably, it is possible to use NH₃, a reductive Si compound, carboxylic acid. As for the reductive Si compound, it is preferable to use a diethylsilane-based compound, e.g., diethylsilane, diethyldichlorosilane or the like. As for the carboxylic acid, it is possible to use a formic acid (HCOOH), an acetic acid (CH₃COOH), a propionic acid (CH₃CH₂COOH), a butyric acid (CH₃(CH₂)₂COOH), a valeric acid (CH₃(CH₂)₃COOH) or the like. Preferably, HCOOH can be used.

When a Cu film is formed, Cu(hfac)TMVS is supplied in a liquid state at a flow rate of about 100 to 500 mg/min. Although the flow rate of the reducing agent is varied depending on types of reducing agents, is about 0.1 to 100 mL/min(sccm).

Cu(hfac)TMVS as a film-forming source material is decomposed on the wafer W as a target substrate heated by the heater 5 of the susceptor 2 by the disproportionate reaction described in the following Eq. (1). As a result, Cu is produced.

2Cu(hfac)TMVS→Cu+Cu(hfac)₂+2TMVS Eq. (1)

Among the monovalent Cu β-diketone complexes, Cu(hfac)TMVS has a lowest thermal decomposition temperature. However, in order to proceed the reaction of the above Eq. (1), Cu(hfac)TMVS needs to be heated at a relatively high temperature of about 150 to 200° C. Therefore, migration of Cu on the surface of the Cu film is facilitated during film formation and an agglutination reaction occurs, which makes it difficult to obtain a smooth Cu film.

Moreover, Cu(hfac)TMVS as a monovalent Cu β-diketone complex produces, as a by-product, Cu(hfac)₂ having a low vapor pressure during the film formation. The by-product thus produced is adsorbed on the surface of the formed film. Thus, the adsorption of Cu(hfac)TMVS is hindered, and the initial nucleus density of Cu is decreased. Accordingly, the smoothness of the Cu film is deteriorated.

In the present embodiment, Cu is produced by reducing Cu(hfac)TMVS as a monovalent Cu β-diketone complex by a reducing agent, and the thus-produced Cu is deposited on the wafer W.

The activation energy of the reduction reaction by the reducing agent is lower than that of the reaction of the above Eq. (1), so that the reduction reaction proceeds at a temperature lower than that of the thermal decomposition reaction of the above Eq. (1). Hence, the film formation temperature can be decreased to about 130° C.

The reducing agent is easily adsorbed on the base compared to Cu(hfac)₂ as a by-product. When Cu(hfac)TMVS is supplied to the site where the reducing agent is adsorbed, the reduction occurs, which results in production and adsorption of Cu. Accordingly, the initial nucleus density of Cu can be increased.

Due to the effect of decreasing the film formation temperature and the effect of increasing the initial nucleus density of Cu, a smooth high-quality Cu film can be obtained.

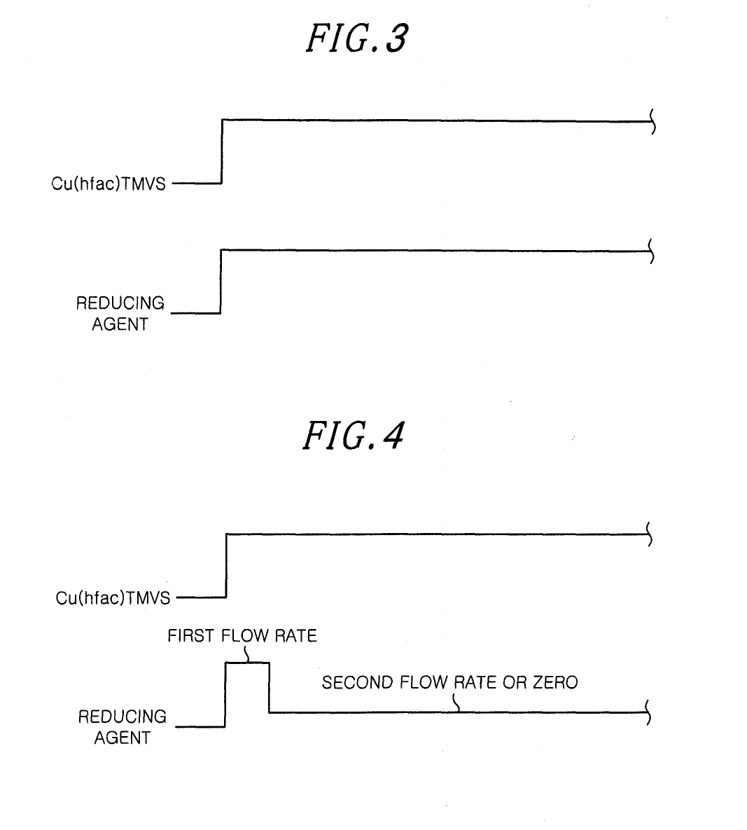

As shown in FIG. 3, the film forming sequence includes the simultaneously supply of Cu(hfac)TMVS and the reducing agent. In the example of FIG. 3, the flow rate of the reducing agent is the same from the start of the film formation to the end thereof. However, as shown in FIG. 4, the reducing agent may be supplied at a first flow rate during the initial stage of the film formation and then may be supplied at a second flow rate lower than the first flow rate or may not be supplied (flow rate of zero). Although this reduces the effect of decreasing the film formation temperature, the absorption of the reducing agent into the film can be prevented, and the quality of the Cu film can be further increased.

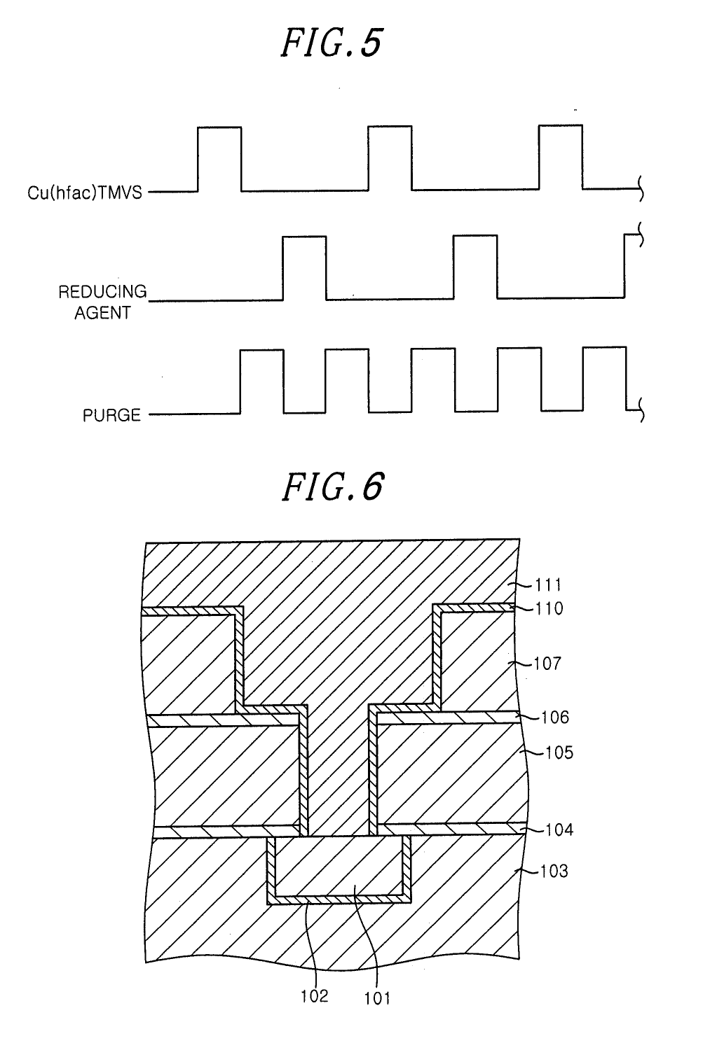

In the film forming sequence, there may be used so-called ALD (Atomic Layer Deposition) in which Cu(hfac)TMVS and the reducing agent are supplied alternately with a purge process interposed therebetween as shown in FIG. 5. The purge process can be performed by supplying a carrier gas. The film formation temperature can be further decreased by ALD.

After the Cu film is formed in the above-described manner, the purge process is performed. In the purge process, the interior of the chamber 1 is purged by supplying a carrier gas as a purge gas into the chamber 1 while stopping the supply of Cu(hfac)TMVS and setting the vacuum pump of the gas exhaust unit 23 to a pull-end state. In this case, it is preferable to intermittently supply the carrier gas in order to rapidly purge the interior of the chamber 1.

Upon completion of the purge process, the gate valve G opens, and the wafer W is unloaded via the loading/unloading port 25 by a transfer device (not shown). Accordingly, a series of processes for a single wafer W is completed.

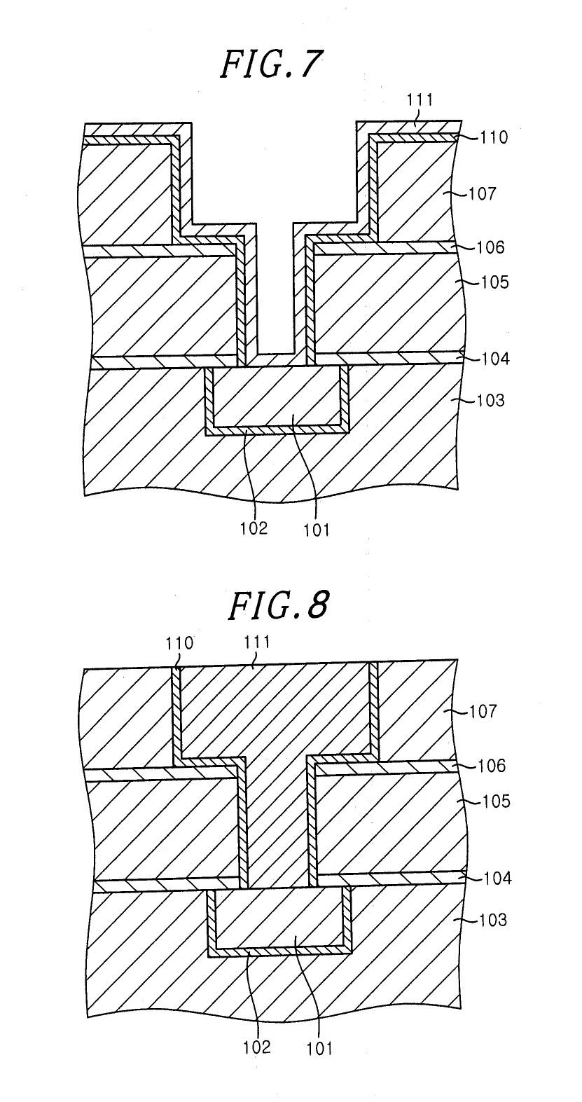

The CVD-Cu film thus formed can be used as a wiring material or a Cu plating seed layer. When the CVD-Cu film is used as a wiring material, the CVD-Cu film 111 is formed until the via hole 108 and the trench 109 are covered as shown in FIG. 5. Thus, a wiring and a plug are formed of the CVD-Ru film 111. When the CVD-Cu film is used as a Cu plating seed layer, the CVD-Cu film 111 is thinly formed thinly on the surface of the CVD-Ru film 110 and the exposed surface of the Cu wiring layer 101 as shown in FIG. 7.

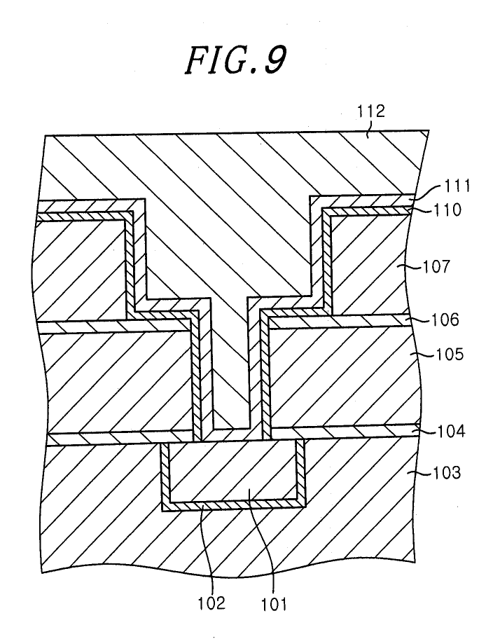

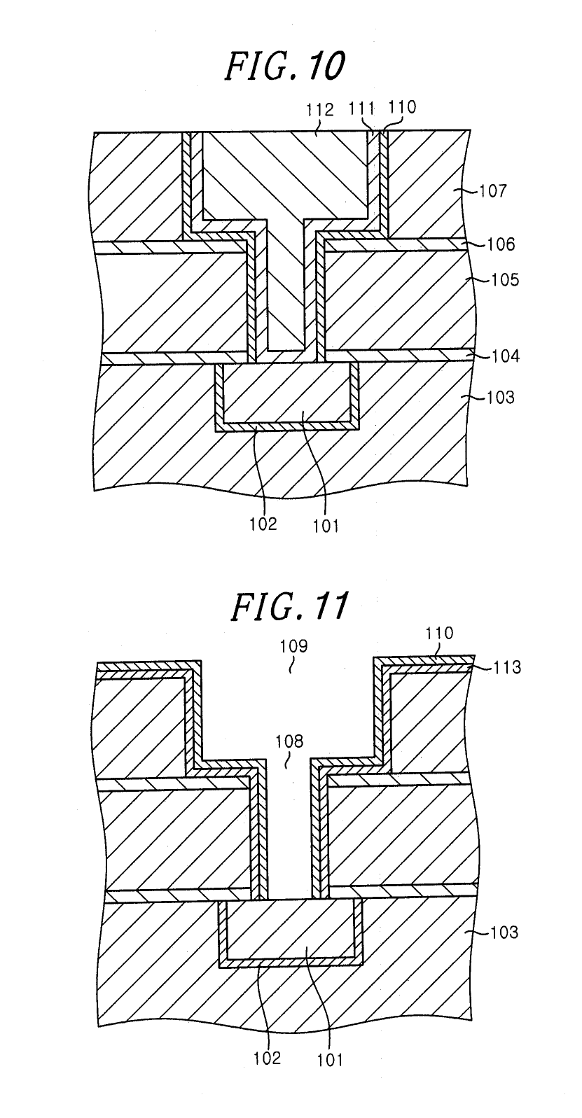

When the wiring and the plug are formed of the CVD-Cu film 111 as shown in FIG. 6, excessive Cu is removed by performing CMP (chemical mechanical polishing) such that the wiring insulating film 107 and the CVD-Cu film 111 are positioned on the same plane as shown in FIG. 8. When the CVD-Cu film 111 is thinly formed as a Cu plating seed layer as shown in FIG. 7, the wiring and the plug are formed of a Cu plating layer 112 as shown in FIG. 9. Then, excessive Cu is removed by performing CMP such that the wiring insulating film 107 and the Cu plating layer 112 are positioned on the same plane as shown in FIG. 10.

In the above example, a single layer of the CVD-Ru film 110 is used as a barrier layer (diffusion prevention layer). However, as shown in FIG. 11, a laminated structure of the CVD-Ru film 110 as an upper layer and a high-melting point material film 113 as a lower layer may be used. In this case, one of Ta, TaN, Ti, W, TiN, WN, manganese oxide and the like can be used for the lower layer.

In accordance with the present embodiment, a Cu film is formed on the wafer W as a target substrate by CVD by introducing a monovalent Cu P-diketone complex and a reducing agent for reducing the monovalent Cu β-diketone complex in a vapor state into the chamber 1 as a processing chamber. Therefore, the film formation can be performed at a low temperature while decreasing the activation energy of the film formation reaction. Moreover, the reducing agent is adsorbed on the base in the initial stage of the film formation, so that the initial nucleus density of Cu can be increased. Accordingly, a Cu film having high smoothness can be obtained.

### <Another Embodiment of the Present Invention>

The present invention can be variously modified without being limited to the above embodiment. For example, although the case in which Cu(hfac)TMVS is used as a Cu complex having a vapor pressure higher than that of a by-product produced by thermal decomposition has been described in the above embodiment, it is not limited thereto. As described above, another monovalent Cu β-diketone complex such as Cu(hfac)MHY, Cu(hfac)ATMS, Cu(hfac)DMDVS, Cu(hfac)TMOVS, Cu(hfac)COD or the like can be used. Besides, the reducing agent is not limited to the above-described one. Further, although the case in which a CVD-Ru film is used as a base film has been described, it is not limited thereto.

In the above embodiment, a Cu complex in a liquid state is force-fed to a vaporizer and then is vaporized therein. However, it may be vaporized in a different manner, e.g., bubbling or the like, other than the above-described manner.

Further, the film forming apparatus is not limited to that of the above embodiment, and there can be used various apparatuses such as one including a mechanism for forming a plasma to facilitate decomposition of a film-forming source material gas and the like.

The structure of the target substrate is not limited to those shown in FIGS. 2 and 10. Although the case in which a semiconductor wafer is used as a substrate to be processed has been described, another substrate such as a flat panel display (FPD) substrate or the like may also be used without being limited thereto.

While the invention has been shown and described with respect to the embodiments, it will be understood by those skilled in the art that various changes and modifications may be made without departing from the scope of the invention as defined in the following claims.

What is claimed is:

1. A method for forming a Cu film, comprising:
loading a substrate in a processing chamber;
introducing into the processing chamber a monovalent Cu β-diketone complex and a reducing agent for reducing the monovalent Cu β-diketone complex in a vapor state; and
forming a Cu film by reducing the monovalent Cu β-diketone complex by the reducing agent and depositing Cu on the substrate by CVD.

2. The method of claim 1, wherein the reducing agent is NH₃.

3. The method of claim 1, wherein the reducing agent is a reductive Si compound.

4. The method of claim 3, wherein the reductive Si compound is a diethylsilane-based compound.

5. The method of claim 1, wherein the reducing agent is carboxylic acid.

6. The method of claim 1, wherein the monovalent Cu β-diketone complex is copper hexafluoroacetylacetonate trimethylvinylsilane (Cu(hfac)TMVS).

7. The method of claim 1, wherein the Cu film is formed by simultaneously supplying the monovalent Cu β-diketone complex and the reducing agent into the processing chamber.

8. The method of claim 7, wherein the reducing agent is supplied at a first flow rate in an initial stage of film formation and then is supplied at a second flow rate lower than the first flow rate or at a flow rate of zero.

9. The method of claim 1, wherein the monovalent Cu β-diketone complex and the reducing agent are supplied alternately with the supply of a purge gas therebetween.

10. The method of claim 1, wherein the substrate has on a surface thereof an Ru film formed by CVD, and the Cu film is formed on the Ru film.

11. The method of claim 10, wherein the Ru film is formed by using Ru₃(CO)₁₂ as a film-forming source material.

12. The method of claim 10, wherein the Ru film is used as at least a part of a diffusion prevention film.

13. The method of claim 12, wherein the diffusion prevention film has as a base layer of the Ru film a high melting point material film.

14. The method of claim 13, wherein the high melting point material film is made of at least one selected from the group consisting of Ta, TaN, Ti, W, TiN, WN and manganese oxide.

15. The method of claim 1, wherein the Cu film is used as a wiring material.

16. The method of claim 1, wherein the formed Cu film is used as a Cu plating seed layer.

17. A computer readable storage medium storing a program for controlling a film forming apparatus,
wherein the program, when executed, controls the film forming apparatus to perform a method for forming a Cu film which includes:
loading a substrate in a processing chamber;
introducing into the processing chamber a monovalent Cu β-diketone complex and a reducing agent for reducing the monovalent Cu β-diketone complex in a vapor state; and
forming a Cu film by reducing the monovalent Cu β-diketone complex by the reducing agent and depositing Cu on the substrate by CVD.
